(19) United States
(12) Patent Application Publication
(10) Pub. No.: US 2023/0330806 A1
(43) Pub. Date: Oct. 19, 2023

(54) POLISHING PAD WITH IMPROVED WETTABILITY AND METHOD FOR PREPARING SAME

(71) Applicant: SK enpulse Co., Ltd., Gyeonggi-do (KR)

(72) Inventors: Chang Gyu IM, Gyeonggi-do (KR); Jangwon SEO, Gyeonggi-do (KR); Jong Wook YUN, Gyeonggi-do (KR); Sunghoon YUN, Gyeonggi-do (KR)

(21) Appl. No.: 18/298,378

(22) Filed: Apr. 11, 2023

(30) Foreign Application Priority Data
Apr. 18, 2022 (KR) 10-2022-0047693

(51) Int. Cl. B24B 37/24; B24B 37/22

(52) U.S. Cl. CPC B24B 37/24; B24B 37/22

(57) ABSTRACT

The present invention discloses a polishing pad comprising a laminate composed of a polishing layer, an adhesive layer, and a cushion layer, wherein the cushion layer has a water absorption rate of 100% or less, and a process for manufacturing the polishing pad.

### CROSS-REFERENCE TO RELATED APPLICATION(S)

This application claims priority under 35 U.S.C. § 119 to Korean Patent Application No. 10-2022-0047693, filed on Apr. 18, 2022, the disclosure of which is incorporated herein by reference in its entirety.

### TECHNICAL FIELD

The embodiments relate to a polishing pad for use in a chemical mechanical planarization (CMP) process of semiconductors and a process for manufacturing the same.

### BACKGROUND ART

A polishing pad for a CMP process is an essential element that plays an important role in the CMP process for the fabrication of semiconductors. A polishing pad for a CMP process serves to remove unnecessary portions on a wafer and makes the surface of the wafer smooth through a uniform polishing operation during the CMP process.

Mechanical polishing in a CMP process is performed by bringing a silicon wafer into contact with a polishing layer having a certain roughness on its surface and causing friction by moving them relative to each other. Chemical polishing is performed by injecting a slurry containing a chemical abrasive between a polishing pad and a wafer to have the surface of the wafer reacted with the slurry.

In such an event, a polishing pad for CMP has a laminated structure of a polishing layer, an adhesive layer, and a cushion layer. In order to prevent the degradation of polishing quality due to the surface hardening of a polishing layer, a polishing pad for CMP must always be kept wet with distilled water or a slurry during polishing.

However, distilled water or a slurry may be absorbed into the polishing pad, particularly the cushion layer, from a part of the lateral side or the upper side of the polishing pad during a polishing process. A polishing pad whose compressibility is locally reduced due to the water absorption of the cushion layer applies more pressure to the wafer during a CMP process, resulting in uneven polishing speed and deterioration in quality. In particular, when a polishing pad is used for a long period of time, the water absorption of the cushion layer intensifies, which increases the volume of the edge portion as compared with the central portion and significantly reduces the compressibility; thus, it is difficult to achieve a uniform polishing layer during the polishing of a wafer due to a large difference in polishing rate between the central portion and the edge portion.

In addition, due to the water absorption of the cushion layer, the adhesive force with the polishing layer is weakened during a CMP process, which may cause lifting at the edge portion. In severe cases, and the polishing layer may be partially delaminated and derailed from the position for the polishing process.

In order to solve this problem, methods of heat sealing the edge of the lower pad (Korean Patent No. 10-1890331) or coating the edge of the polishing pad with a waterproof material (Korean Patent No. 10-0785604) have been used. Even with these methods, there is a limit to improving the problems of local changes in compressibility due to water absorption of the surface portion and a difference in polishing rate or weakening of adhesive force during long-term use.

### Prior Art Document

[Patent Document]

(Patent Document 1) Korean Patent No. 10-1890331

(Patent Document 2) Korean Patent No. 10-0785604

### DISCLOSURE OF INVENTION

### Technical Problem

In order to solve the above problems, the present invention aims to provide a polishing pad capable of preventing water absorption that may occur during a CMP process by enhancing the waterproof or water repellency of the cushion layer through the following embodiments and a process for manufacturing the same.

### Solution to Problem

According to an embodiment, there is provided a polishing pad, which comprises a laminate composed of a polishing layer, an adhesive layer, and a cushion layer, wherein the cushion layer has water repellency, and the cushion layer has a water absorption rate of 100% or less.

According to another embodiment, there is provided a process for manufacturing a polishing pad, which comprises preparing a cushion layer; applying an adhesive to the back side of the polishing surface of a polishing layer and to one side of the cushion layer; and adhering the back side of the polishing surface of the polishing layer and the one side of the cushion layer by high-temperature pressing, wherein the cushion layer has a water absorption rate of 100% or less.

### Advantageous Effects of Invention

The polishing pad according to the embodiment can enhance the waterproof or water repellency of a cushion layer to reduce the water absorption rate at the lateral side or upper side that may occur during a CMP process, thereby enhancing the polishing yield of wafers.

Specifically, the polishing pad can impart water repellency to a cushion layer itself, thereby minimizing the local changes in compressibility and reducing the changes in compressibility of the polishing pad even after a long-term polishing process; thus, it is possible to enhance polishing rate uniformity, within-wafer non-uniformity of a wafer, and production yield.

In addition, it is possible to reduce the changes in volume of the cushion layer due to water absorption, which prevents the adhesive strength of the adhesive layer from being weakened, thereby preventing the lifting phenomenon between the cushion layer and the polishing layer. Thus, the efficiency in the manufacturing process of wafers can be further enhanced, resulting in industrial benefits.

Accordingly, when the polishing pad according to the embodiment is used, it is possible to reduce the occurrence of defects such as scratches on a wafer and to improve the polishing precision by suppressing non-uniform polishing, thereby providing a semiconductor element of high quality.

### BRIEF DESCRIPTION OF DRAWINGS

FIG. 1 schematically illustrates the process for manufacturing a semiconductor device according to an embodiment.

FIG. 2 shows a laminated structure of a polishing pad in which the base layer comprises a surface coating layer according to an embodiment.

FIG. 3 shows a laminated structure of a polishing pad in which the base layer is impregnated according to an embodiment.

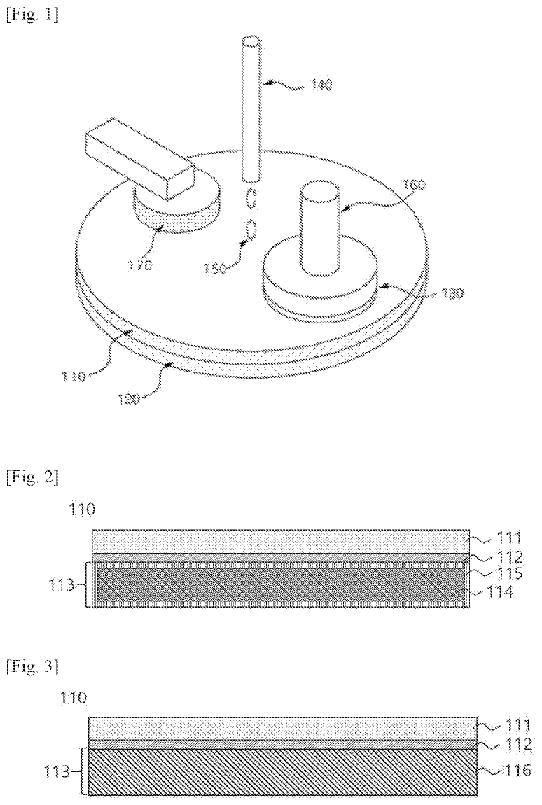

[Reference Numeral of the Drawings]

| | |
|---|---|
| 110: polishing pad | 120: platen |
| 130: semiconductor substrate | 140: nozzle |
| 150: polishing slurry | 160: polishing head |
| 170: conditioner | |
| 111: polishing layer | 112: adhesive layer |
| 113: cushion layer | 114: base layer |
| 115: surface coating layer | 116: impregnated base layer |

### BEST MODE FOR CARRYING OUT THE INVENTION

Hereinafter, the embodiments will be described in detail with reference to the accompanying drawings so that those of ordinary skill in the art to which the present invention pertains can easily implement the present invention. However, the embodiments may be implemented in various different forms and are not limited to those described in the present specification.

Throughout the present specification, when a part is referred to as “comprising” an element, it is understood that other elements may be comprised, rather than other elements are excluded, unless specifically stated otherwise.

Throughout the description of the embodiments, in the case where each layer, hole, window, or region is mentioned to be formed “on” or “under” another layer, hole, window, or region, it means not only that one element is “directly” formed on or under another element, but also that one element is “indirectly” formed on or under another element with other element(s) interposed between them.

In addition, the term on or under with respect to each element may be referenced to the drawings. For the sake of description, the sizes of individual elements in the appended drawings may be exaggeratedly depicted and do not indicate the actual sizes.

### Polishing Pad

The polishing pad according to an embodiment comprises a laminate composed of a polishing layer, an adhesive layer, and a cushion layer.

Cushion Layer

The cushion layer serves to support the polishing layer and to absorb and disperse an impact applied to the polishing layer.

The cushion layer is a cushion layer with improved wettability, and the cushion layer comprises a base layer. In an embodiment of the present invention, the base layer may comprise a surface coating layer in order to improve the wettability of the cushion layer.

In an embodiment of the present invention, the base layer may be impregnated with a water-repellent resin to improve wettability.

In an embodiment of the present invention, the base layer may be a nonwoven fabric or a porous pad formed by comprising at least one resin selected from the group consisting of a polyester resin, a polyamide resin, a polyurethane resin, a polyolefin resin, and a fluoropolymer resin.

The method for obtaining the base layer of the present invention is not particularly limited, but single component spinning, sea-island composite spinning, or split composite spinning may be used. In addition, spun-bonded or melt-blown, long-fiber nonwoven fabrics directly formed from spinning, nonwoven fabrics obtained by papermaking, what is obtained by spraying, dipping, or coating nanofibers on a support, woven or knitted fabrics, or the like may be used. A long-fiber nonwoven fabric obtained by a spun-bonding method is preferable from the viewpoints of the tensile strength of the sheet-like material, manufacturing cost, and the like.

The long-fiber nonwoven fabric is preferably contracted or densified by dry heat, moist heat, or both from the viewpoint of densification.

The base layer may contain pores. The pores contained in the base layer may have a structure of an opened cell. The porosity of the base layer may be greater than the porosity of the polishing layer.

The base layer may have a thickness of 0.5 mm to 2.5 mm. For example, the thickness of the base layer may be 0.7 mm to 2.3 mm, 0.8 mm to 2.0 mm, 1.0 mm to 1.6 mm, 1.1 mm to 1.5 mm, or 1.3 mm to 1.4 mm, but it is not limited thereto. If the thickness of the base layer is within the above range, sufficient support performance during polishing may be imparted to the cushion layer.

In an embodiment of the present invention, the cushion layer comprises a base layer, wherein the base layer may comprise a surface coating layer formed from a coating composition comprising a fluorine-based resin or a silane-based resin, or the base layer may be impregnated with an impregnation composition comprising a fluorine-based resin or a silane-based resin.

The coating composition or impregnation composition may be formed from a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, a polyamide-based elastomer resin, a fluorine-based resin, and a silane-based resin.

The fluorine-based resin may be at least one resin selected from the group of resins having hydrophobicity, and it may be a resin having a compound containing a hydroxyl group, an isocyanate group, an epoxy group, or an amine group at its terminal.

The fluorine-based resin may be a urethane-based prepolymer that is a copolymer of a prepolymer composition comprising an isocyanate compound, an alcohol compound, and a fluorine-based compound comprising a fluorine-based repeat unit, but it is not limited thereto.

The fluorine-based compound may react with an isocyanate to introduce a fluorine-based repeat unit into the main chain of urethane.

Specifically, the fluorine-based compound may be a compound comprising, in its molecule, a fluoroalkylene group having 1 to 10 carbon atoms, an ethylene oxide group containing fluorine in a branch, and/or a fluorocarbon group having 1 to 10 carbon atoms and comprising a hydroxyl group, isocyanate group, epoxy group, or amine at the terminal.

The fluorine-based compound may be a fluorine-based compound comprising a fluorine-based repeat unit represented by the following Formula 1 and having a hydroxyl group, an amine group, or an epoxy group at at least one terminal.

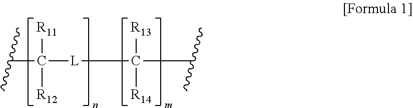

In Formula 1, R₁₁ and R₁₂ are each independently any one selected from the group consisting of hydrogen, an alkyl group having 1 to 10 carbon atoms, and fluorine, provided that at least one of R₁₁ and R₁₂ is fluorine, and L is an alkylene having 1 to 5 carbon atoms or —O—. In addition, Ria and Rio are each independently any one selected from the group consisting of hydrogen, an alkyl group having 1 to 10 carbon atoms, and fluorine, provided that at least one of R₁₃ and R₁₄ is fluorine. In addition, n is an integer of 0 to 20, and m is an integer of 0 to 20, provided that both n and m are not 0 at the same time.

Specifically, in Formula 1, R₁₁ and R₁₂ are each independently any one selected from the group consisting of hydrogen, an alkyl group having 1 to 5 carbon atoms, and fluorine, provided that at least one of R₁₁ and R₁₂ is fluorine, and L is an alkylene having 1 to 5 carbon atoms or —O—. In addition, R₁₃ and R₁₄ are each independently any one selected from the group consisting of hydrogen, an alkyl group having 1 to 5 carbon atoms, and fluorine, provided that at least one of R₁₃ and R₁₄ is fluorine. In addition, n is an integer of 0 to 10, and m is an integer of 0 to 10, provided that both n and m are not 0 at the same time.

The fluorine-based compound may be a compound represented by the following Formula 2.

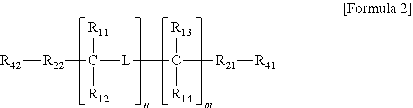

In Formula 2, R₁₁ and R₁₂ are each independently any one selected from the group consisting of hydrogen, an alkyl group having 1 to 10 carbon atoms, and fluorine, provided that at least one of R₁₁ and R₁₂ is fluorine, and L is an alkylene having 1 to 5 carbon atoms or —O—, R₁₃ and R₁₄ are each independently any one selected from the group consisting of hydrogen, an alkyl group having 1 to 10 carbon atoms, and fluorine, provided that at least one of R₁₃ and R₁₄ is fluorine, n is an integer of 0 to 20, and m is an integer of 0 to 20, provided that both n and m are not 0 at the same time, R₂₁ and R₂₂ are each independently —(CH₂)ₘ₁— or —(CH₂)ₘ₂—(OCH₂CH₂)ₘ₃— (provided that m1, m2, and m3 are each independently an integer of 1 to 20), and R₄₁ and R₄₂ are each independently a hydroxyl group, an amine group, or an epoxy group.

The fluorine-based compound may be employed in an amount of 0.1 to 4.9% by weight, 2 to 4% by weight, or 2.5 to 3.5% by weight, based on the total weight of the prepolymer composition. If the fluorine-based compound is employed in an amount of less than 0.1% by weight based on the total weight of the prepolymer composition, the effect of reducing defects by comprising the fluorine-based compound may be insignificant. If it is employed in an amount exceeding 4.9% by weight, gelation may occur during the synthesis process, making it difficult to carry out the synthesis process to obtain the intended physical properties, and the water repellency increases beyond the required level, thereby weakening the adhesive strength between the respective layers of the polishing pad and causing the delamination of the respective layers during the manufacture or use of the polishing pad, resulting in deterioration in the performance of the polishing pad. If the fluorine-based compound is employed in the above content, it is possible to provide a polishing pad having an excellent effect of defect reduction.

The silane-based resin may be at least one resin selected from the group of resins having hydrophobicity, and it may preferably be a resin having a compound containing a hydroxyl group, an isocyanate group, an epoxy group, or an amine group at its terminal.

The silane-based resin may be a urethane-based prepolymer that is a copolymer of a prepolymer composition comprising an isocyanate compound, an alcohol compound, and a silane-based compound comprising a silane-based repeat unit, but it is not limited thereto.

The silane-based compound may react with an isocyanate to introduce a silane-based repeat unit into the main chain of urethane.

Specifically, the silane-based compound may be a silane-based compound comprising a silane-based repeat unit represented by the following Formula 3 and having a hydroxyl group, an amine group, or an epoxy group at at least one terminal.

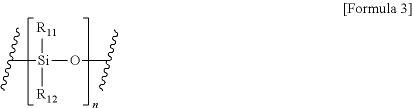

In Formula 3, R₁₁ and R₁₂ are each independently hydrogen or an alkyl group having 1 to 10 carbon atoms, and n is an integer of 1 to 30.

Specifically, in Formula 3, R₁₁ and R₁₂ may each independently be hydrogen or an alkyl group having 1 to 5 carbon atoms, and n may be an integer of 8 to 28.

The silane-based compound may be a compound represented by the following Formula 4.

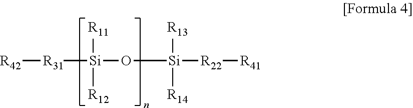

In Formula 4, R₁₁, R₁₂, R₁₃, and R₁₄ are each independently hydrogen or an alkyl group having 1 to 10 carbon atoms, R₂₂ is —(CH₂)ₘ₁— or —(CH₂)ₘ₂—(OCH₂CH₂)ₘ₃— (provided that m1, m2, and m3 are each independently an integer of 1 to 20), R₃₁ is an alkylene group having 1 to 20 carbon atoms, R₄₁ and R₄₂ are each independently a hydroxyl group, an amine group, or an epoxy group, and n is an integer of 1 to 30.

The silane-based compound may be employed in an amount of 0.1 to 4.9% by weight, 2 to 4% by weight, or 2.5 to 3.5% by weight, based on the total weight of the prepolymer composition. If the silane-based compound is employed in an amount of less than 0.1% by weight based on the total weight of the prepolymer composition, the effect of reducing defects by comprising the silane-based compound may be insignificant. If it is employed in an amount exceeding 4.9% by weight, gelation may occur during the synthesis process, making it difficult to carry out the synthesis process to obtain the intended physical properties, and the water repellency increases beyond the required level, thereby weakening the adhesive strength between the respective layers of the polishing pad and causing the delamination of the respective layers during the preparation or use of the polishing pad, resulting in deterioration in the performance of the polishing pad. If the silane-based compound is employed in the above content, it is possible to provide a polishing pad having an excellent effect of defect reduction.

In the fluorine-based resin and the silane-based resin, the isocyanate compound may be any one selected from p-phenylene diisocyanate, 1 ,6-hexamethylene diisocyanate, toluene diisocyanate, 1,5-naphthalene diisocyanate, isophorone diisocyanate, 4,4-diphenylmethane diisocyanate, cyclohexylmethane diisocyanate, and combinations thereof, but it is not limited thereto.

In the fluorine-based resin and the silane-based resin, the alcohol compound may comprise at least one of polyol compounds or monomolecular alcohol compounds.

The polyol compound may be any one selected from the group consisting of a polyester polyol, a polyether polyol, a polycarbonate polyol, a polycaprolactone polyol, and combinations thereof, but it is not limited thereto.

The monomolecular alcohol compound may be any one selected from the group consisting of ethylene glycol, diethylene glycol, propylene glycol, trimethylene glycol, methyl propanediol, and combinations thereof, but it is not limited thereto.

If a polyurethane resin comprising a fluorine-based compound or a silane-based compound is used as the coating composition, the water absorption rate of the cushion layer of a polishing pad is reduced, and the compressibility and changes in compressibility of the polishing pad are minimized even after a long-term polishing process; thus, it is possible to provide a polishing pad having an excellent effect of defect reduction.

FIG. 2 shows a laminated structure of a polishing pad (110) in which a polishing layer (111) and a cushion layer (113) are combined by an adhesive layer (112). In addition, the cushion layer (113) comprises a base layer (114) and a surface coating layer (115), and the surface coating layer (115) is formed on the surface of the base layer.

The surface coating layer may be prepared by a dipping method in which a cushion layer is cut to the size of a final product, immersed in a bath containing a polyurethane resin comprising a fluorine-based compound or a silane-based compound, taken out, cured, dried, and then used.

All the surfaces of the cushion layer prepared by the dipping method are coated, so that water can hardly penetrate into its inside.

In an embodiment of the present invention, the surface coating layer may be formed on one or more surfaces or the entire surfaces of the base layer.

For example, the surface coating layer may be formed on two or more surfaces including the upper and lateral sides of the base layer or formed on the entire surfaces of the base layer.

In an embodiment of the present invention, the surface coating layer may have a thickness of 75 μm to 125 μm, 80 μm to 120 μm, 85 μm to 115 μm, 90 μm to 110 μm, or 95 μm to 105 μm.

The surface coating layer may have the same thickness on each surface or may have a different thickness on each surface. For example, the thickness of the surface coating layer located on the upper side may be 80 μm to 120 μm, and the thickness of the surface coating layer located on the lateral side may be 80 μm to 120 μm.

If the thickness of the surface coating layer is within the above range, the water absorption rate of the cushion layer of a polishing pad may be effectively reduced upon contact with distilled water or a slurry. Since the changes in compressibility and in volume of the polishing pad may be minimized, thereby reducing defects and scratches; thus, the quality of wafers produced can be improved. In addition, in a pad comprising a window, it is possible to extend the lifespan of the polishing pad by preventing dew formation on the window.

FIG. 3 shows a laminated structure of a polishing pad according to an embodiment. A polishing layer (111) and a cushion layer (113) are combined by an adhesive layer (112), and the cushion layer (113) comprises an impregnated base layer (116).

It is preferable to impart a polymeric elastomer containing polyurethane as a main component by impregnation before the long-fiber nonwoven fabric of the base layer is processed into ultrafine fibers. This is because the binder effect of the polymeric elastomer prevents the ultrafine fibers from falling off the polishing cloth and enables the ultrafine fibers and the polymer resin to be uniformly dispersed when exposed on the surface of the base layer.

Although the impregnating composition used for imparting the polymeric elastomer is as described above, N,N′-dimethylformamide, dimethylsulfoxide, or the like may be preferably used as a solvent, and an aqueous emulsion form may be applied. A nonwoven fabric is immersed in a solution in which a polymer resin for impregnation is dissolved in a solvent to impart a polymeric elastomer to the nonwoven fabric, which is then dried to substantially solidify the polymeric elastomer. In drying, it may be heated to a temperature that does not impair the performance of the nonwoven fabric and the polymeric elastomer.

According to another embodiment of the present invention, the cushion layer may be one in which a surface coating layer is additionally formed on one side or the entire sides of the base layer impregnated with the polymer resin for impregnation. It is possible to produce a more excellent effect if the surface coating layer is additionally formed on a base layer impregnated with a fluorine-based resin or a silane-based resin to impart water repellency.

Physical properties of the cushion layer In an embodiment of the present invention, the cushion layer may have a contact angle of 76° to 90°. For example, the contact angle of the cushion layer may be 80° to 90°, 82° to 89°, 85° to 89°, 84° to 87°, 84° to 86.5°, 87° to 89°, or 87.5° to 88.5°, but it is not limited thereto.

If the contact angle is within the above range, the surface energy of the surface may be reduced to minimize the amount of water absorption. In addition, the change in contact angle of the cushion layer may increase the bonding force with an adhesive used when a pad is prepared, so that the probability of delamination during the polishing of wafers can be reduced, and the possibility of water penetration into the pad can be reduced.

The cushion layer of the present invention may have a density of 0.1 g/cm³ to 0.6 g/cm³, 0.3 g/cm³ to 0.5 g/cm³, or 0.3 g/cm³ to 0.4 g/cm³.

The cushion layer is classified into a cushion layer in a dry state and a cushion layer in a wet state depending on whether or not water or a slurry is contained in the cushion layer. Here, a cushion layer in a wet state may be one in which water is absorbed by immersing the cushion layer in a dry state in a bath containing water or a slurry for 12 to 48 hours, or water is absorbed through a polishing process for 12 to 48 hours. For example, a cushion layer in a wet state may be one in which a dry cushion layer is immersed in a bath containing water for 24 hours to absorb water, but it is not limited thereto. In addition, a cushion layer in a wet state may be one in which a polishing pad comprising a dry cushion layer is used in a polishing process for 25 hours, whereby the cushion layer absorbs water, but it is not limited thereto.

The cushion layer of the present invention may have a water absorption rate of 100% or less derived by the following Equation (1). For example, the water absorption rate derived by Equation (1) may be 90% or less, 80% or less, 70% or less, 60% or less, 50% or less, 40% or less, 30% or less, 20% or less, 17% or less, 15% or less, or 10% or less, but it is not limited thereto.

As the water absorption rate is adjusted within the above range, it is possible to control the changes in mechanical properties such as compressibility or hardness of a cushion layer, changes in electrical properties, and/or changes in polishing characteristics of wafers as necessary.

$$Water absorption rate ( \% ) = \frac{W 1 - W 2}{W 1} \times 100 \qquad Equation ( 1 )$$

In Equation (1), W1 is the weight (g) of a specimen obtained by cutting the cushion layer to 35 mm in length and in width, and W2 is the weight (g) of the specimen measured after it is immersed in water for 24 hours.

The cushion layer of the present invention may have a dry compressibility of 3% to 15%, 4% to 13%, 5% to 10%, 5% to 8%, or 5% to 6% according to the following Equation (2), but it is not limited thereto.

$$Dry Compressibility ( \% ) = \frac{D 1 - D 2}{D 1} \times 100 \qquad Equation ( 2 )$$

In Equation (2), D1 and D2 are the thickness (μm) of a specimen obtained by cutting the cushion layer to a size of 25 mm in length and in width when measured after an adhesive tape is attached to the upper and lower sides of the specimen, which is then pressed for 30 seconds with a weight of 85 g and further pressed for 3 minutes with an additional weight of 800 g, respectively.

The cushion layer of the present invention may have a wet compressibility of 5.0% to 6.6%, 5.0% to 6.5%, 5.2% to 6.3%, 5.3% to 6.1%, 5.7% to 6.1%, or 5.3% to 5.5% according to the following Equation (3), but it is not limited thereto.

$$Wet Compressibility ( \% ) = \frac{D 3 - D 4}{D 3} \times 100 \qquad Equation ( 3 )$$

In Equation (3), D3 and D4 are the thickness (um) of a specimen obtained by cutting the cushion layer to a size of 25 mm in length and in width when measured after an adhesive tape is attached to the upper and lower sides of the specimen, which is then immersed in water for 24 hours, pressed for 30 seconds with a weight of 85 g, and further pressed for 3 minutes with an additional weight of 800 g, respectively.

The compressibilities are parameters representing the ratio of the degree of change in thickness of the cushion layer when a weak force and a strong force are applied.

A polishing pad to which a cushion layer having a compressibility satisfying the above range has been applied has a bearing capacity capable of securing excellent polishing performance and can minimize scratches to be formed on an object to be polished. Specifically, in a polishing pad to which a cushion layer having a compressibility falling outside the above range has been applied, polishing performance such as polishing rate or within-wafer non-uniformity may deteriorate, and scratches may be formed on an object to be polished, thereby deteriorating the quality of the object to be polished.

That is, as the compressibility of the cushion layer satisfies the above range, it is possible for a polishing pad thus prepared to minimize scratches formed on an object to be polished, as well as it is easy to planarize materials requiring high surface flatness such as silicon wafers by virtue of its excellent polishing rate and within-wafer non-uniformity.

The cushion layer of the present invention may have a dry compressive elasticity of 55% or less according to the following Equation (4), but it is not limited thereto.

$$Dry compressive elasticity ( \% ) = \frac{D 5 - D 2}{D 1 - D 2} \times 100 \qquad Equation ( 4 )$$

In Equation (4), D1 and D2 are the thickness (μm) of a specimen obtained by cutting the cushion layer to a size of 25 mm in length and in width when measured after an adhesive tape is attached to the upper and lower sides of the specimen, which is then pressed for 30 seconds with a weight of 85 g and further pressed for 3 minutes with an additional weight of 800 g, respectively.

D5 is the thickness (μm) of a specimen obtained by cutting the cushion layer to a size of 25 mm in length and in width when measured after an adhesive tape is attached to the upper and lower sides of the specimen, which is then pressed for 30 seconds with a weight of 85 g, further pressed for 3 minutes with an additional weight of 800 g, and left for 1 minute after the weight of 800 g is removed.

The cushion layer of the present invention may have a wet compressive elasticity of 60% or less, 58% or less, 57% or less, 56% or less, or 55% or less, according to the following Equation (5), but it is not limited thereto.

$$Wet compressive elasticity ( \% ) = \frac{D 6 - D 4}{D 3 - D 4} \times 100 \qquad Equation ( 5 )$$

In Equation (5), D3 and D4 are the thickness (μm) of a specimen obtained by cutting the cushion layer to a size of 25 mm in length and in width when measured after an adhesive tape is attached to the upper and lower sides of the specimen, which is then immersed in water for 24 hours, pressed for 30 seconds with a weight of 85 g, and further pressed for 3 minutes with an additional weight of 800 g, respectively.

D6 is the thickness (μm) of a specimen obtained by cutting the cushion layer to a size of 25 mm in length and in width when measured after an adhesive tape is attached to the upper and lower sides of the specimen, which is immersed in water for 24 hours, then pressed for 30 seconds with a weight of 85 g, further pressed for 3 minutes with an additional weight of 800 g, and left for 1 minute after the weight of 800 g is removed.

The compressive elasticity is a parameter related to the degree of recovery after a strong force is applied to a cushion layer for a certain period of time.

A polishing pad in which a cushion layer having a compressive elasticity satisfying the above range is employed may secure excellent polishing performance even after use for a long period of time while scratches formed on an object to be polished are minimized. Specifically, in a polishing pad to which a cushion layer having a compressive elasticity falling outside the above range has been applied, polishing performance may not be constant as the polishing performance rapidly deteriorates when it is used for a long period of time, and scratches may be formed on an object to be polished, thereby deteriorating the quality of the object to be polished.

That is, in a polishing pad comprising a cushion layer whose compressive elasticity satisfies the above range, it is possible to minimize defects such as scratches formed on an object to be polished, to maintain constant polishing performance, and to secure excellent polishing rate and within-wafer non-uniformity.

The compressibilities and compressive elasticities of a cushion layer can be designed by comprehensively controlling not only the material and composition of the cushion layer, but also the mechanical properties, physical structures, and process conditions, post-processing conditions, and storage/aging conditions of the cushion layer.

The compressive elasticity is related to the water absorption rate of a cushion layer. The higher the water absorption rate, the more water the cushion layer can absorb, and the larger the repulsive force to return to the original state when the cushion layer is pressed, whereby the compressive elasticity may be increased.

The cushion layer may have a change in compressibility of 30% or less or 20% or less according to the following Equation (6).

$$Change in compressibility ( \% ) = ( 1 - \frac{D 1}{D 3} \times \frac{D 3 - D 4}{D 1 - D 2} ) \times 100 \qquad Equation ( 6 )$$

In Equation (6), D1 and D2 are the thickness (μm) of a specimen obtained by cutting the cushion layer to a size of 25 mm in length and in width when measured after an adhesive tape is attached to the upper and lower sides of the specimen, which is then pressed for 30 seconds with a weight of 85 g and further pressed for 3 minutes with an additional weight of 800 g, respectively.

D3 and D4 are the thickness (μm) of a specimen obtained by cutting the cushion layer to a size of 25 mm in length and in width when measured after an adhesive tape is attached to the upper and lower sides of the specimen, which is then immersed in water for 24 hours, pressed for 30 seconds with a weight of 85 g, and further pressed for 3 minutes with an additional weight of 800 g, respectively.

If the change in compressibility satisfies the above range, the amount of impact applied to the polishing layer in a desirable range during polishing is transmitted to the cushion layer, and the physical energy of the polishing layer itself is high, whereby the polishing rate and polishing uniformity are enhanced. The cushion layer and the polishing layer may be laminated for use to achieve a desired polishing performance, and the polishing performance can be maintained constant even after polishing is performed for a certain period of time.

If it falls outside the above range, the amount of energy transmitted to the cushion layer increases. Since the cushion layer has a lot of non-uniform pores, the energy is not uniformly absorbed, so that the within-wafer non-uniformity of the polishing surface becomes not uniform, and the polishing rate may be lowered.

Polishing Layer

The polishing layer may be formed from a polishing layer composition that comprises a first urethane-based prepolymer, a curing agent, and a foaming agent.

A prepolymer generally refers to a polymer having a relatively low molecular weight wherein the degree of polymerization is adjusted to an intermediate level so as to conveniently mold a molded article to be finally produced in the process of producing the same.

A prepolymer may be molded by itself or after a reaction with another polymerizable compound. Specifically, the first urethane-based prepolymer may be prepared by reacting an isocyanate compound with a polyol and may comprise an unreacted isocyanate group (NCO).

The curing agent may be at least one of an amine compound and an alcohol compound. Specifically, the curing agent may comprise at least one compound selected from the group consisting of an aromatic amine, an aliphatic amine, an aromatic alcohol, and an aliphatic alcohol.

The foaming agent is not particularly limited as long as it is commonly used for forming voids in a polishing pad. For example, the foaming agent may be at least one selected from a solid phase foaming agent having a hollow structure, a liquid phase foaming agent using a volatile liquid, and an inert gas.

The polishing layer may contain pores. The pores may have a structure of a closed cell. The average diameter of the pores may be 5 μm to 200 μm. In addition, the polishing layer may contain 20% by volume to 70% by volume of pores relative to the total volume of the polishing layer. That is, the porosity of the polishing layer may be 20% by volume to 70% by volume.

The average thickness of the polishing layer may be 0.8 mm to 5.0 mm, 1 0 mm to 4.0 mm, 1.0 mm to 3.0 mm, 1.5 mm to 2.5 mm, 1.7 mm to 2.3 mm, or 2.0 mm to 2.1 mm.

The hardness of the polishing layer may be 40 Shore D to 80 Shore D, 50 Shore D to 80 Shore D, 40 Shore D to 70 Shore D, 50 Shore D to 70 Shore D, or 55 Shore D to 65 Shore D.

The upper side of the polishing layer may have a concave-convex structure in order to maintain and replace a slurry. In addition, the concave-convex structure generally has a regularity; however, it is possible to change the groove pitch, groove width, groove depth, and the like at specific locations for the purpose of maintaining and replacing a slurry.

The polishing layer may have a transparent window for use to determine the termination point at which the process is terminated by detecting a point at which the desired surface characteristics or thickness is obtained.

A light beam is directed through a window to the surface of a wafer to be processed, and it is reflected back through the window to a detector. The surface characteristics of the wafer can be measured based on the return signal.

The window may be prepared by a method in which a first penetrating hole is formed in the polishing layer, a third penetrating hole (arbitrary configuration) passing through the adhesive layer and a second penetrating hole passing through the cushion layer are formed, and a window is inserted into the first penetrating hole and its periphery is sealed.

Adhesive Layer

The polishing pad may comprise an adhesive layer interposed between the cushion layer and the polishing layer.

The adhesive layer serves to adhere the polishing layer and the cushion layer to each other. Further, the adhesive layer may suppress a polishing liquid from leaking from the upper part of the polishing layer downward the cushion layer.

In addition, a part of the adhesive layer may adhere the window and the cushion layer. Specifically, a part of the adhesive layer may be disposed between a part of the lower side of the window and the cushion layer. In addition, a part of the adhesive layer may be disposed between a part of the lateral side of the window and the cushion layer.

The polishing layer and the cushion layer may be directly bonded to each other without using an adhesive layer. In such an event, the window and the cushion layer may be directly bonded to each other without using an adhesive layer or may be bonded to each other by an adhesive layer.

The adhesive layer may comprise a hot melt adhesive. The hot melt adhesive may be at least one selected from the group consisting of a polyurethane resin, a polyester resin, an ethylene-vinyl acetate resin, a polyamide resin, and a polyolefin resin.

The thickness of the adhesive layer may be 20 μm to 30 μm, specifically 23 μm to 27 μm.

The polishing pad may further comprise a double-sided adhesive tape on the lower side of the cushion layer and may serve to adhere the polishing pad and a platen.

### Process for Manufacturing a Polishing Pad

The process for manufacturing a polishing pad according to an embodiment comprises preparing a cushion layer; applying an adhesive to the back side of the polishing surface of a polishing layer and to one side of the cushion layer; and adhering the back side of the polishing surface of the polishing layer and the one side of the cushion layer by high-temperature pressing, wherein the cushion layer has a water absorption rate of 100% or less according to the following Equation (1).

$$Water absorption rate ( \% ) = \frac{W 2 - W 1}{W 1} \times 100 \qquad Equation ( 1 )$$

In Equation (1), W1 is the weight (g) of a specimen obtained by cutting the cushion layer to 35 mm in length and in width, and W2 is the weight (g) of the specimen measured after it is immersed in water for 24 hours.

Specifically, W1 may be the weight (g) of the cushion layer in a dry state, and W2 may be the weight (g) of the cushion layer measured after it is immersed in water for 24 hours.

In the step of preparing a cushion layer, the cushion layer comprises a base layer, and the step may specifically comprise at least one from a method in which a surface coating layer is formed from a coating composition comprising a fluorine-based resin or a silane-based resin on the base layer to prepare a cushion layer, and a method in which the base layer is impregnated with a resin comprising a fluorine-modified polyurethane resin or a silane-modified polyurethane resin to prepare a cushion layer.

The polishing layer may use a commercially available polishing layer or may be prepared by a conventional method comprising the steps of preparing a composition by sequentially or simultaneously mixing a urethane-based prepolymer, a curing agent, and a foaming agent; and injecting the composition into a mold and curing it. In addition, the above manufacturing process may further comprise the steps of cutting and grinding the surface of a polishing pad thus obtained, machining grooves on the surface thereof, and the like.

Thereafter, a first penetrating hole may be formed in the polishing layer by a punching process. A second penetrating hole may be formed in the cushion layer by a punching process.

In addition, when the polishing layer and the cushion layer are bonded to each other, the first penetrating hole in the polishing layer and the second penetrating hole in the cushion layer may be aligned to correspond to each other.

The polishing layer and the cushion layer may be adhered to each other, which may be achieved through a first adhesive layer disposed between the polishing layer and the cushion layer. Specifically, the first adhesive layer may be disposed under the lower side of the polishing layer or on the upper side of the cushion layer, and the polishing layer and the cushion layer may be adhered by the first adhesive layer.

As described above, the first adhesive layer may comprise a hot melt adhesive, and the polishing layer and the cushion layer may be bonded to each other by applying heat and/or pressure. A window is inserted into the first penetrating hole.

Thereafter, the window may be adhered to the cushion layer. Specifically, the window may be inserted into the first penetrating hole and adhered to the cushion layer at the same time. That is, the window may be adhered to the cushion layer by a part of the first adhesive layer. The window may be adhered to the cushion layer by heat and/or pressure.

Physical Properties of the Polishing Pad

Since the polishing pad thus prepared has excellent water repellency of the sub-pad of the cushion layer, the water absorption of purified water or a slurry on the upper side or lateral side during a polishing process such as CMP can be suppressed. Specifically, the water absorption of purified water or a slurry at the corners around the outer periphery of the cushion layer and the corners of the penetrating holes of the cushion layer used for the detection of a termination point may be suppressed or prevented.

In addition, in the polishing pad, it is possible to suppress the water absorption of purified water or a slurry into the cushion layer even if the slurry leaks between the window and the penetrating hole of the polishing layer and to prevent a change in compressibility due to wetting of the cushion layer.

The polishing pad of the present invention may have a dry compressibility of 1.0% to 2.5%. For example, the dry compressibility of the polishing pad may be 1.2% to 2.3%, 1.4% to 2.1%, or 1.5% to 1.9%, but it is not limited thereto.

The polishing pad of the present invention may have a wet compressibility of 0.8% to 1.7%. For example, the wet compressibility of the polishing pad may be 0.9% to 1.7%, 1.0% to 1.6%, 1.1% to 1.6%, 1.1% to 1.4%, or 1.5% to 1.6%, but it is not limited thereto.

A polishing pad in which a laminate having a dry compressibility and a wet compressibility satisfying the above ranges is employed may have a supporting force capable of securing excellent polishing performance while scratches formed on an object to be polished are minimized.

In an embodiment of the present invention, the polishing pad may have a change in compressibility of 50% or less according to the following Equation (7). For example, the change in compressibility of the polishing pad may be 40% or less, 30% or less, 20% or less, or 10% or less, according to the following Equation (7).

$$Change in compressibility ( 5 ) = ( 1 - \frac{P 1}{P 3} \times \frac{P 3 - P 4}{P 1 - P 2} ) \times 100 \qquad Equation ( 7 )$$

In Equation (7), P1 and P2 are the thickness (μm) of a specimen obtained by cutting the polishing pad to a size of 25 mm in length and in width when measured after it is pressed for 30 seconds with a weight of 85 g and further pressed for 3 minutes with an additional weight of 800 g, respectively.

P3 and P4 are the thickness (μm) of a specimen obtained by cutting the polishing pad to a size of 25 mm in length and in width when measured after it is immersed in a bath containing water for 24 hours, then pressed for 30 seconds with a weight of 85 g, and further pressed for 3 minutes with an additional weight of 800 g, respectively.

If the change in compressibility satisfies the above range, the amount of impact applied to the polishing layer in a desirable range during polishing is transmitted to the cushion layer, and the physical energy of the polishing layer itself is high, whereby the polishing rate and polishing uniformity are enhanced, resulting in an excellent quality.

The interfacial adhesion of the polishing pad is measured by using a universal testing machine (UTM) device to measure the interfacial adhesion between the polishing layers and the cushion layers using a 180° peel strength method. The interfacial adhesion may be 6.0 kgf/25 mm to 7.7 kgf/25 mm, 6.3 kgf/25 mm to 7.7 kgf/25m, 6.3 kgf/25 mm to 7.5 kgf/25 mm, 6.5 kgf/25 mm to 7.5 kgf/25 mm, or 6.8 kgf/25 mm to 7.4 kgf/25 mm.

The interfacial adhesion may decrease due to the coating or impregnation of the cushion layer. If the interfacial adhesion falls within the above range, however, a sufficient adhesive force of the polishing pad required during a polishing process may be provided, and it is possible to prevent a part of the polishing layer from being separated and derailing from the position for the polishing process.

The polishing pad of the present invention may have a polishing rate of 2,500 A/minute to 3,000 A/minute.

In an embodiment of the present invention, the polishing pad may have a within-wafer non-uniformity of 3.5% or less according to the following Equation (8). For example, the within-wafer non-uniformity of the polishing pad may be 3.0% or less, 2.5% or less, 2.4% or less, or 2.3% or less, according to the following Equation (8).

Within-wafer non-uniformity (%)=(standard deviation of polished thickness (Å)/average polished thickness(Å))×100(%) Equation (8)

If the within-wafer non-uniformity of the polishing pad is within the above range, it is easy to planarize the surface of an object to be polished requiring high surface flatness, and it is possible to provide a semiconductor device of excellent quality.

As to the durability of the polishing pad of the present invention, no bubbles or tears are observed on the polishing surface when the polishing pad is observed with the naked eye upon completion of the polishing process for 25 hours.

The polishing pad of the present invention can reduce defects in silicon wafers manufactured using the polishing pad of the present invention by virtue of the uniform transmittance of energy. For example, it is possible to reduce the occurrence of defects by 85% or more, 88% or more, or 92% or more.

Upon completion of a polishing process for 25 hours with the polishing pad of the present invention, the number of defects may be 3 or less. Specifically, the number of defects may be 2 or less, 1 or less, or 0.

Since the polishing pad of the present invention can significantly reduce the degree of defects, while maintaining the same level of cut pad rate and polishing rate as those of conventional polishing pads, the defect rate of silicon wafers due to defects can be significantly reduced.

### MODE FOR THE INVENTION

Hereinafter, the present invention is explained in detail by Examples. The following Examples are intended to further illustrate the present invention, and the scope of the Examples is not limited thereto.

### EXAMPLE

### Preparation of a Cushion Layer

### Preparation Examples 1 to 3

A polyester fiber non-woven fabric was impregnated with a polyurethane resin (100 parts by weight of a polyurethane resin composed of 0.7 mole of a polytetramethylene glycol having an average molecular weight of 3,000 and 0.3 moles of an aliphatic diamine relative to 1.0 mole of an aliphatic diisocyanate was dispersed in water together with 5 parts by weight of an emulsifier), which was cured in an oven at 130° C. and then dried to prepare sheets having a total thickness of 1.6 mm, 1.4 mm, and 1.0 mm, respectively.

### Preparation Examples 4 to 6

An aqueous solution obtained by adding 3 parts by weight of a fluorine-based resin (Solvay, Fluorolink E10-H) to 100 parts by weight of the polyurethane resin used in Preparation Example 1 was applied to one side of each sheet of Preparation Examples 1 to 3 by a dipping method, which was cured in an oven at 130° C. and dried to form a coating layer having a thickness of 100 μm.

### Preparation Examples 7 to 9

A polyester fiber non-woven fabric was impregnated with an aqueous solution obtained by adding 3 parts by weight of a silane-based resin (Wacker, IM 11) to the polyurethane resin used in Preparation Example 1, which was cured in an oven at 130° C. and then dried to prepare sheets having a total thickness of 1.6 mm, 1.4 mm, and 1.0 mm, respectively.

In Preparation Examples 4 to 9, a fluorine-based resin was used for the coating layer, and a silane-based resin for impregnation, but the silane-based resin may be used for the coating, and the fluorine-based resin for impregnation.

### Preparation of a Polishing Pad

### Example 1

A polyurethane-based adhesive (Youngchang Chemical, HMF 27) as a heat-sealing adhesive was applied to the back side of the polishing surface of a polishing layer to a thickness of 27 μm, and the heat-sealing adhesive was applied to one side of each cushion layer of Preparation Examples 1 to 9 to a thickness of 27 μm. Subsequently, the back side of the polishing surface of the polishing layer was placed in contact with the one side of the cushion layer of Preparation Example 4, which was pressurized based on a 50% gap of arithmetic thickness using a pressure roller under a condition of 120° C. to adhere the polishing layer and the cushion layer. Subsequently, it was left under a condition of 25° C. for 24 hours for post-treatment to prepare a polishing pad.

### Examples 2 to 6 and Comparative Examples 1 to 3

A polishing pad was manufactured in the same manner as in Example 1, except that the cushion layers of Preparation Examples 1 to 3 and 5 to 9 were each used as shown in Table 4 below instead of the cushion layer of Preparation Example 4.

### TEST EXAMPLE

### Hardness

The cushion layer samples prepared in Preparation Examples 1 to 9 were each cut into 5 cm×5 cm, and an acrylic adhesive tape, in which an acrylic adhesive having an adhesive strength of 2,200 gf/inch or more was applied to both sides of PSA (a PET base sheet having a thickness of 50 μm) with a PET liner having a thickness of 75 μm, was used on the upper and lower sides to form an adhesive layer for testing. It was stored at a temperature of 25° C. for 12 hours, and the Asker C hardness was measured using a durometer.

### Compressibility and Compressive Elasticity

For the cushion layer samples prepared in Preparation Examples 1 to 9, a specimen having a size of 25 mm in length and in width was taken from a location of 30 mm in the edge, and an acrylic adhesive tape, in which an acrylic adhesive having an adhesive strength of 2,200 gf/inch or more was applied to both sides of PSA (a PET base sheet having a thickness of 50 μm) with a PET liner having a thickness of 75 μm, was used on the upper and lower sides to form an adhesive layer for testing.

In addition, for the polishing pad samples prepared in Examples 1 to 6 and Comparative Examples 1 to 3, a specimen having a size of 25 mm in length and in width was taken from a location of 30 mm in the edge. The dial gauge of each specimen was measured in the no-load state. It was pressed with a standard weight of 85 g, and the first thickness (D1) was measured when 30 seconds elapsed. An additional weight of 800 g was placed on the specimen, which had been pressed with the standard weight, for a pressurized condition of 885 g in total, the second thickness (D2) was measured when 3 minutes elapsed. Thereafter, the dry compressibility (%) was derived using the following Formula (2).

$$Dry compressibility ( \% ) = \frac{D 1 - D 2}{D 1} \times 100 \qquad Equation ( 2 )$$

In Equation (2), D1 and D2 were the thickness (pm) of a specimen obtained by cutting the cushion layer to a size of 25 mm in length and in width when measured after an adhesive tape was attached to the upper and lower sides of the specimen, which was then pressed for 30 seconds with a weight of 85 g and further pressed for 3 minutes with an additional weight of 800 g, respectively.

The weight of 800 g under the pressurized condition was removed, and it was left for 1 minute. The third thickness (D5) was measured, and the dry compressive elasticity (%) was derived using the following Formula (4).

$$Dry compressive elasticity ( \% ) = \frac{D 5 - D 2}{D 1 - D 2} \times 100 \qquad Equation ( 4 )$$

In Equation (4), D5 was the thickness (μm) of a specimen obtained by cutting the cushion layer to a size of 25 mm in length and in width when measured after an adhesive tape was attached to the upper and lower sides of the specimen, which was then pressed for 30 seconds with a weight of 85 g, further pressed for 3 minutes with an additional weight of 800 g, and left for 1 minute after the weight of 800 g is removed.

For the wet compressibility and the wet compressive elasticity, the specimen was immersed in a bath containing water for 24 hours to sufficiently absorb water and then taken out to remove water on both sides. The first thickness (D3), the second thickness (D4), and the third thickness (D6) were measured. The wet compressibility and the wet compressive elasticity were derived using the following Equations (3) and (5).

$$Wet compressibility ( \% ) = \frac{D 3 - D 4}{D 3} \times 100 \qquad Equation ( 3 )$$

In Equation (3), D3 and D4 were the thickness (pm) of a specimen obtained by cutting the cushion layer to a size of 25 mm in length and in width when measured after an adhesive tape was attached to the upper and lower sides of the specimen, which was then immersed in water for 24 hours, pressed for 30 seconds with a weight of 85 g, and further pressed for 3 minutes with an additional weight of 800 g, respectively.

$$Wet compressive elasticity ( \% ) = \frac{D 6 - D 4}{D 3 - D 4} \times 100 \qquad Equation ( 5 )$$

In Equation (5), D6 was the thickness (μm) of a specimen obtained by cutting the cushion layer to a size of 25 mm in length and in width when measured after an adhesive tape was attached to the upper and lower sides of the specimen, which was immersed in water for 24 hours and then pressed for 30 seconds with a weight of 85 g, further pressed for 3 minutes with an additional weight of 800 g, and left for 1 minute after the weight of 800 g is removed.

### Water Absorption Rate

For the cushion layer samples prepared in Preparation Examples 1 to 9, the weight (W1) of a specimen having a size of 35 mm in width and in length was measured, and it was immersed in a bath containing water for 24 hours to sufficiently absorb water. Thereafter, the specimen was taken out to measure the weight (W2), and the water absorption rate (%) was calculated using the following Equation (1).

$$Water absorption rate ( \% ) = \frac{W 2 - W 1}{W 1} \times 100 \qquad Equation ( 1 )$$

In Equation (1), W1 was the weight (g) of a specimen obtained by cutting the cushion layer to 35 mm in length and width, and W2 was the weight (g) of the specimen measured after it was immersed in water for 24 hours.

### Contact Angle

According to the standard test method (ASTM D 5946), water droplets were dropped on the surface of each cushion layer prepared in Preparation Examples 1 to 9, and the angle between the virtual tangent to the edge where the water droplets were in contact with the surface of the cushion layer and the surface of the cushion layer was measured using a contact angle measuring instrument (DST-60).

### Interfacial Adhesion

The interfacial adhesion of each polishing pad prepared in Examples 1 to 6 and Comparative Examples 1 to 3 was measured by using a universal testing machine (UTM) device to measure the interfacial adhesion between the polishing layers and the cushion layers using a 180° peel strength method. Here, a specimen was cut into a size of 25 mm×300 mm in width and in length, the gripping position was measured with a margin of about 50 mm of each specimen, and the test speed was 300 mm/minute.

The polishing conditions using the polishing pads of Examples and Comparative Examples are shown in Table 1 below.

TABLE 1

| | Item | Details |
|---|---|---|
| Wafer | Type | PETEOS |
| | Dummy (time/number) | 300 s/∞ |
| Break-in | Time (minute) | 15 |
| Polishing | Rotational speed of the polishing | 87 |
| head | head (rpm) | |
| and platen | Pressure of the polishing head (psi) | 3.5 |
| | Pressure of the retainer ring (psi) | 9 |
| | Rotational speed of the platen (rpm) | 93 |
| | Spindle sweep speed (sw/minute) | 19 |
| Condi- | Type | CI-45 |
| tioner | | (Seasol Diamond) |
| | Condition | In situ (300 s), |
| | | Ex situ (15 s) |
| | Weight (lb) | 6 |
| | Rotational speed (rpm) | 101 |
| | Sweep speed (sw/minute) | 19 |
| Slurry | Type | TSO-12 |
| | | (Advantech Korea) |

The polishing pads prepared in Examples 1 to 6 and Comparative Examples 1 to 3 were each measured and evaluated for the following physical properties. The results are shown in Table 4 below.

### Polishing Rate

In CMP polishing equipment, a PETEOS wafer was set on the platen to which the polishing pads prepared in Examples 1 to 6 and Comparative Examples 1 to 3 were each attached. Thereafter, polishing was performed under a polishing load of 3.5 psi while the platen was rotated at a speed of 93 rpm for 30 seconds and a TSO-12 slurry (Advantech Korea) was supplied onto the polishing pad at a rate of 190 ml/minute. Upon completion of the polishing, the silicon wafer was detached from the carrier, mounted in a spin dryer, washed with deionized water (DIW), and then dried with air for 15 seconds. The difference in film thickness of the dried silicon wafer before and after the polishing was measured using a contact-type sheet resistance measuring instrument (with a 4-point probe). The polishing rate was calculated using the following Equation.

Polishing rate (Å/minute)=polished thickness of a silicon wafer(Å)/polishing time (minute)

### Within-Wafer Non-Uniformity

A polishing process was carried out for each of the polishing pads prepared in Examples 1 to 6 and Comparative Examples 1 to 3 under the same conditions as the method for measuring the polishing rate. Then, the in-plane film thickness of the water at 98 points was measured, and the within-wafer non-uniformity (%) was derived according to the following Equation (8).

Within-wafer non-uniformity(%)=(standard deviation of polished thickness(Å)/average polished thickness(Å))×100(%) Equation (8)

### Durability

For each of the polishing pads prepared in Examples 1 to 6 and Comparative Examples 1 to 3, a polishing process was carried out under the same conditions as the method for measuring the polishing rate, while the polishing time was set to 25 hours, and the polishing pad upon completion of the polishing was observed with the naked eye to check whether bubbles were formed on the polishing surface, tearing of the polishing pad, and the like.

### Number of Surface Defects

After the polishing process was carried out using each of the polishing pads of Examples 1 to 6 and Comparative Examples 1 to 3, the residues, scratches, and chatter marks appearing on the wafer surface upon the polishing was measured using a wafer inspection device (AIT XP+, KLA Tencor) (threshold: 150, die filter threshold: 280).

Specifically, upon the polishing, the silicon wafer was transferred to a cleaner and cleaned for 10 seconds each using 1% HF, purified water (DIW), 1% H₂NO₃, and purified water (DIW). Thereafter, it was transferred to a spin dryer, washed with purified water (DIW), and then dried with nitrogen for 15 seconds. The dried silicon wafer was measured for the changes in defects before and after the polishing using the wafer inspection device.

TABLE 2

| | | | | Hardness | | Contact | Water |
|---|---|---|---|---|---|---|---|
| | Cushion | Thickness | Density | (Asker C) | | angle | absorption rate |
| | layer | (mm) | (g/cm³) | Dry | Wet | (°) | (%) |
| Surface | Prep. Ex. 1 | 1.6 | 0.33 | 85 | 83 | 75.3 | 124 |
| non-treated | Prep. Ex. 2 | 1.4 | 0.34 | 86 | 86 | 74.5 | 130 |
| | Prep. Ex. 3 | 1.0 | 0.33 | 85 | 84 | 74.9 | 121 |
| Surface | Prep. Ex. 4 | 1.6 | 0.37 | 87 | 86 | 87.8 | 14 |
| coating | Prep. Ex. 5 | 1.4 | 0.37 | 86 | 86 | 88.2 | 15 |
| | Prep. Ex. 6 | 1.0 | 0.38 | 85 | 84 | 88.5 | 17 |
| Impregnation | Prep. Ex. 7 | 1.6 | 0.32 | 86 | 84 | 86.4 | 11 |
| | Prep. Ex. 8 | 1.4 | 0.31 | 84 | 85 | 85.2 | 10 |
| | Prep. Ex. 9 | 1.0 | 0.33 | 83 | 82 | 84.3 | 9 |

TABLE 3

| | | Compressibility | | Compressive | |
|---|---|---|---|---|---|
| | Cushion | (%) | | elasticity (%) | |
| | layer | Dry | Wet | Dry | Wet |
| Surface | Prep. Ex. 1 | 5.2 | 6.7 | 54 | 65 |
| non-treated | Prep. Ex. 2 | 5.4 | 6.9 | 52 | 62 |
| | Prep. Ex. 3 | 5.1 | 6.8 | 55 | 67 |
| Surface | Prep. Ex. 4 | 5.8 | 5.7 | 54 | 55 |
| Coating | Prep. Ex. 5 | 6.0 | 6.1 | 53 | 52 |
| | Prep. Ex. 6 | 5.8 | 5.9 | 53 | 51 |
| Impregnation | Prep. Ex. 7 | 5.3 | 5.4 | 52 | 49 |
| | Prep. Ex. 8 | 5.5 | 5.3 | 53 | 52 |
| | Prep. Ex. 9 | 5.6 | 5.5 | 51 | 54 |

As shown in Tables 2 and 3, the cushion layers of Preparation Examples 4 to 9 had a significantly reduced water absorption rate (change rate in weight during water absorption) and a significantly reduced change in compressibility as compared with the cushion layers of Preparation Examples 1 to 3. In addition, when the surface was coated, the surface contact angle could be increased to impart hydrophobicity to the surface.

Preparation Examples 4 to 9 having water repellency by surface coating or impregnation showed similar values of compressibility and compressive elasticity in dry and wet conditions. In contrast, Preparation Examples 1 to 3 having no water repellency showed large changes in compressibility and compressive elasticity of similar values in dry and wet conditions. This is attributable to the fact that, in Preparation Examples 1 to 3, the initial thickness became relatively thick due to expansion in a state of water absorption, resulting in a large difference in thickness before and after compression in Preparation Examples 1 to 3.

TABLE 4

| | | Interfacial | | | | Within- | | |
|---|---|---|---|---|---|---|---|---|
| | | adhesion | | | | wafer non- | | Number of |
| Polishing | Cushion | (kgf/25 | Compressibility (%) | | Polishing rate | uniformity | | surface |
| pad | layer | mm) | Dry | Wet | (Å/minute) | (%) | Durability | defects |
| Ex. 1 | Prep. Ex. 4 | 7.12 | 1.7 | 1.4 | 2,894 | 2.2 | No | 0 |
| | | | | | | | abnormality | |
| Ex. 2 | Prep. Ex. 5 | 6.85 | 1.6 | 1.3 | 2,947 | 2.0 | No | 1 |
| | | | | | | | abnormality | |
| Ex. 3 | Prep. Ex. 6 | 7.35 | 1.7 | 1.2 | 2,797 | 2.3 | No | 1 |
| | | | | | | | abnormality | |
| Ex. 4 | Prep. Ex. 7 | 7.32 | 1.6 | 1.5 | 2,856 | 2.3 | No | 1 |
| | | | | | | | abnormality | |
| Ex. 5 | Prep. Ex. 8 | 6.92 | 1.5 | 1.5 | 2,795 | 2.4 | No | 2 |
| | | | | | | | abnormality | |
| Ex. 6 | Prep. Ex. 9 | 6.80 | 1.7 | 1.6 | 2,827 | 2.0 | No | 1 |
| | | | | | | | abnormality | |
| C. Ex. 1 | Prep. Ex. 1 | 7.87 | 1.7 | 1.8 | 2,679 | 4.1 | Bubbles | 5 |
| C. Ex. 2 | Prep. Ex. 2 | 8.92 | 1.8 | 1.9 | 2,873 | 3.9 | Bubbles | 7 |
| C. Ex. 3 | Prep. Ex. 3 | 9.13 | 1.6 | 1.7 | 2,745 | 3.8 | Bubbles | 5 |

As shown in Table 4, the polishing pads of Examples 1 to 6 had smaller changes in compressibility in dry and wet states than those of the polishing pads of Comparative Examples 1 to 3, and the physical energy of the polishing layers themselves was increased, resulting in excellent polishing rate and within-wafer non-uniformity.

In addition, bubbles on the polishing surface or tearing of the polishing pad were not observed with the naked eye upon polishing for a certain period of time, and the number of surface defects was significantly reduced; thus, it was possible to provide a polishing pad having an excellent defect reduction effect.

1. A polishing pad, which comprises a laminate composed of a polishing layer, an adhesive layer, and a cushion layer, wherein the cushion layer has a water absorption rate of 100% or less according to the following Equation (1):
$$Water absorption rate ( \% ) = \frac{W 2 - W 1}{W 1} \times 100 \qquad Equation ( 1 )$$
in Equation (1), W1 is the weight (g) of a specimen obtained by cutting the cushion layer to 35 mm in length and in width, and W2 is the weight (g) of the specimen measured after it is immersed in water for 24 hours.

2. The polishing pad of claim 1, wherein the cushion layer comprises a base layer,
the base layer comprises a surface coating layer formed from a coating composition comprising a fluorine-based resin or a silane-based resin, or
the base layer is impregnated with an impregnation composition comprising a fluorine-based resin or a silane-based resin.

3. The polishing pad of claim 2, wherein the surface coating layer has a thickness of 80 μm to 120 μm.

4. The polishing pad of claim 2, wherein the base layer is a nonwoven fabric comprising at least one resin selected from the group consisting of a polyester resin, a polyamide resin, a polyurethane resin, a polyolefin resin, and a fluoropolymer resin, and
the base layer has a thickness of 0.5 mm to 2.5 mm.

5. The polishing pad of claim 1, wherein the cushion layer has a contact angle of 76° to 90°.

6. The polishing pad of claim 1, wherein the cushion layer has a dry compressibility of 3% to 15% according to the following Equation (2):
$$Dry compressibility ( \% ) = \frac{D 1 - D 2}{D 1} \times 100 \qquad Equation ( 2 )$$
in Equation (2), D1 and D2 are the thickness (pm) of a specimen obtained by cutting the cushion layer to a size of 25 mm in length and in width when measured after an adhesive tape is attached to the upper and lower sides of the specimen, which is then pressed for 30 seconds with a weight of 85 g and further pressed for 3 minutes with an additional weight of 800 g, respectively.

7. The polishing pad of claim 6, wherein the cushion layer has a dry compressive elasticity of 55% or less according to the following Equation (4):
$$Dry compressive elasticity ( \% ) = \frac{D 5 - D 2}{D 1 - D 2} \times 100 \qquad Equation ( 4 )$$
in Equation (4), D5 is the thickness (pm) of a specimen obtained by cutting the cushion layer to a size of 25 mm in length and in width when measured after an adhesive tape is attached to the upper and lower sides of the specimen, which is then pressed for 30 seconds with a weight of 85 g, further pressed for 3 minutes with an additional weight of 800 g, and left for 1 minute after the weight of 800 g is removed.

8. The polishing pad of claim 1, wherein the cushion layer has a wet compressibility of 5.0% to 6.6% according to the following Equation (3):
$$Wet compressibility ( \% ) = \frac{D 3 - D 4}{D 3} \times 100 \qquad Equation ( 3 )$$
in Equation (3), D3 and D4 are the thickness (μm) of a specimen obtained by cutting the cushion layer to a size of 25 mm in length and in width when measured after an adhesive tape is attached to the upper and lower sides of the specimen, which is then immersed in water for 24 hours, pressed for 30 seconds with a weight of 85 g, and further pressed for 3 minutes with an additional weight of 800 g, respectively.

9. The polishing pad of claim 8, wherein the cushion layer has a wet compressive elasticity of 60% or less according to the following Equation (5):
$$Wet compressive elasticity ( \% ) = \frac{D 6 - D 4}{D 3 - D 4} \times 100 \qquad Equation ( 5 )$$
in Equation (5), D6 is the thickness (μm) of a specimen obtained by cutting the cushion layer to a size of 25 mm in length and in width when measured after an adhesive tape is attached to the upper and lower sides of the specimen, which is immersed in water for 24 hours and then pressed for 30 seconds with a weight of 85 g, further pressed for 3 minutes with an additional weight of 800 g, and left for 1 minute after the weight of 800 g is removed.

10. The polishing pad of claim 1, wherein the polishing pad has a within-wafer non-uniformity of 3.5% or less.

11. The polishing pad of claim 1, wherein the interfacial adhesion between the polishing layer and the cushion layer is 6.0 kgf/25 mm to 7.7 kgf/25 mm.
